(19) United States
(12) Patent Application Publication
(10) Pub. No.: US 2023/0231032 A1
(43) Pub. Date: Jul. 20, 2023

(54) TRANSISTOR

(71) Applicant: Commissariat á I'Énergie Atomique et aux Énergies Alternatives, Paris (FR)

(72) Inventors: René Escoffier, Grenoble Cedex 9 (FR); Blend Mohamad, Grenoble Cedex 9 (FR)

(73) Assignee: Commissariat á I'Énergie Atomique et aux Énergies Alternatives, Paris (FR)

(21) Appl. No.: 18/010,443

(22) PCT Filed: Jun. 9, 2021
(86) PCT No.: PCT/EP2021/065479

§ 371 Date: Dec. 14, 2022

(30) Foreign Application Priority Data
Jun. 16, 2020 (FR) FR2006259

(51) Int. Cl. H01L 29/66; H01L 29/20; H01L 29/778; H01L 29/423; H01L 29/417

(52) U.S. Cl. CPC H01L 29/66462; H01L 29/2003; H01L 29/7786; H01L 29/4238; H01L 29/41766

(57) ABSTRACT

A transistor including a gate region penetrating into a first gallium nitride layer, wherein a second electrically-conductive layer coats at least one of the sides of said gate region.

The present patent application claims the priority benefit of French patent application FR20/06259 which is herein incorporated by reference.

### TECHNICAL BACKGROUND

The present disclosure generally concerns electronic devices and, more particularly, normally-off high electron mobility transistors (HEMT) based on gallium nitride (GaN).

### PRIOR ART

Gallium nitride normally-off HEMT transistors are used, for example, in electric energy conversion applications, for powers typically in the range from a few milliwatts to several tens of watts. Such transistors generally have a strong on-state resistance or a low threshold voltage, which adversely affects their performance.

### SUMMARY OF THE INVENTION

There is a need to improve existing gallium nitride normally-off high electron mobility transistors.

An embodiment overcomes all or part of the disadvantages of existing gallium nitride normally-off high electron mobility transistors.

An embodiment provides a transistor comprising a gate region penetrating into a first gallium nitride layer, wherein a second electrically-conductive layer coats at least one of the sides of said gate region.

According to an embodiment, the gate region comprises:
a first gate electrode; and
a third electrically-insulating layer, interposed between the first electrode and the first layer.

According to an embodiment, the transistor further comprises a second electrode and a third electrode, located on either side of the gate region and penetrating into the first layer, the second electrode being closer to the gate region than the third electrode.

According to an embodiment:
the second electrode is a source electrode forming part of a source region of the transistor; and
the third electrode is a drain electrode forming part of a drain region of the transistor.

According to an embodiment, the second layer coats the side of the gate region located in front of the second electrode.

According to an embodiment, the second layer is discontinuous and comprises:
a first portion, coating the side of the gate region located in front of the second electrode; and
a second portion, coating the side of the gate region located in front of the third electrode.

According to an embodiment, the first layer coats a surface of a semiconductor substrate.

According to an embodiment, the first layer has a multilayer structure comprising:
a first sub-layer, coating said surface of the substrate;
a second P-type doped sub-layer, coating the first sub-layer; and
a third sub-layer, coating the second sub-layer,
   the gate region crossing the third and second sub-layers and further extending inside of the first sub-layer.

According to an embodiment, the transistor further comprises, on the side of said surface, a stack comprising:
a fourth aluminum-gallium nitride layer coating the first layer; and
a fifth silicon nitride layer, coating the fourth layer.

According to an embodiment, the sides of the gate region are, in side view, inclined towards the middle of the gate region by an angle in the range from 5° to 45°, preferably equal to approximately 10°.

According to an embodiment, the gate region exhibits, in cross-section view, at least one step.

An embodiment provides a method of manufacturing a transistor such as described.

### BRIEF DESCRIPTION OF THE DRAWINGS

The foregoing and other features and advantages of the present invention will be discussed in detail in the following non-limiting description of specific embodiments and implementation modes in connection with the accompanying drawings, in which:

FIG. 1 is a partial simplified cross-section view of an example of a transistor;

FIG. 2 is a partial simplified cross-section view of an embodiment of a transistor;

FIG. 3 is a partial simplified cross-section view of a variant of the transistor of FIG. 2;

FIG. 4 is a partial simplified cross-section view of another embodiment of a transistor;

FIG. 5 is a partial simplified cross-section view of a variant of the transistor of FIG. 4;

FIG. 6 is a partial simplified cross-section view of another variant of the transistor of FIG. 4;

FIG. 7 is a partial simplified cross-section view illustrating a step of an implementation mode of a method of manufacturing the transistor of FIG. 4;

FIG. 8 is a partial simplified cross-section view illustrating another step of the implementation mode of the method of manufacturing the transistor of FIG. 4;

FIG. 9 is a partial simplified cross-section view illustrating still another step of the implementation mode of the method of manufacturing the transistor of FIG. 4;

FIG. 10 is a partial simplified cross-section view illustrating still another step of the implementation mode of the method of manufacturing the transistor of FIG. 4;

FIG. 11 is a partial simplified cross-section view illustrating a variant of the step discussed in relation with FIG. 10;

FIG. 12 is a partial simplified cross-section view illustrating still another step of the implementation mode of the method of manufacturing the transistor of FIG. 4;

FIG. 13 is a partial simplified cross-section view of still another embodiment of a transistor;

FIG. 14 is a partial simplified cross-section view illustrating an electron density inside of the transistor of FIG. 13 in an operating mode;

FIG. 15 is a partial simplified cross-section view illustrating the current density inside of the transistor of FIG. 13 in another operating mode;

FIG. 16 is a graph of the variation of a drain current according to a gate-source voltage of the transistor of FIG. 13; and

FIG. 17 is another graph of the variation of the drain current according to the gate- source voltage of the transistor of FIG. 13.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For clarity, only those steps and elements which are useful to the understanding of the described embodiments and implementation modes have been shown and will be detailed. In particular, the applications and devices likely to take advantage of the described transistors are not detailed, the described transistors being compatible with usual applications and devices comprising gallium nitride normally-off high electron mobility transistors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., unless otherwise specified, it is referred to the orientation of the drawings.

Unless specified otherwise, the terms “about”, “approximately”, “substantially”, and “in the order of” signify within 10% or 10°, preferably within 5% or 5°.

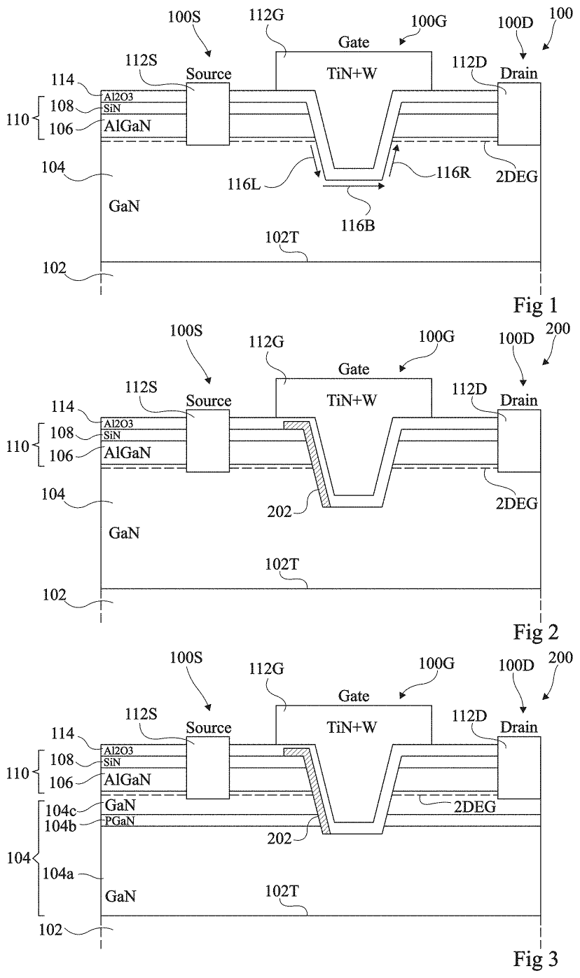

FIG. 1 is a partial simplified cross-section view of an example of a high electron mobility transistor (HEMT) 100, or HEMT transistor. HEMT transistor 100 is normally off in this example.

In the shown example, HEMT transistor 100 is formed on a substrate 102. Substrate 102 is for example a wafer, or a piece of wafer, a single portion of which is shown in FIG. 1. As an example, substrate 102 is made of a semiconductor material (for example, silicon), of glass, or of sapphire.

A first layer 104 (GaN) coats a surface 102T of substrate 102 (the upper surface of substrate 102, in the orientation of FIG. 1). As an example, first layer 104 is made of gallium nitride (GaN), for example of intrinsic (that is, not intentionally doped) gallium nitride.

Further, a second layer 106 (AlGaN) coats first layer 104 on the side of surface 102T of substrate 102. As an example, second layer 106 is made of aluminum-gallium nitride (AlGaN).

In the shown example, a third layer 108 (SiN) coats second layer 106 on the side of surface 102T of substrate 102. As an example, third layer 108 is made of silicon nitride (SiN).

Second layer 106 and third layer 108 form together a stack 110.

Transistor 100 comprises a gate region 100G (Gate). The gate region 100G of transistor 100 is called recessed in first gallium nitride layer 104. More precisely, in the shown example, gate region 100G extends vertically, from the upper surface of third layer 108, towards the upper surface 102T of substrate 102.

In the shown example, the gate region 100G of transistor 100 comprises a gate electrode 112G (TiN+W). Gate electrode 112G has, in cross-section view in FIG. 1, a “T” shape having a vertical portion crossing layers 108 and 106 and partially penetrates into the thickness of layer 104. Further, a horizontal portion of the T formed by gate electrode 112G extends laterally above third layer 108.

In the shown example, the sides of the vertical portion of the T formed by gate electrode 112G are inclined so that they come closer to each other at the bottom of electrode 112G. This enables, in operation, to facilitate the flowing of electrons from one side to the other of electrode 112G. More precisely, the fact for the sides of the vertical portion of the T formed by gate electrode 112G to be inclined advantageously enables to avoid for these sides to form a vertical stop against which electrons would collide.

Gate electrode 112G is made of an electrically-conductive material. As an example, electrode 112G is made of a metal or of a metal alloy, for example, an alloy based on titanium nitride (TiN) and on tungsten (W).

In the shown example, a fourth layer 114 (Al2O3) insulates gate electrode 112G from layers 104, 106, and 108. Fourth layer 114 is made of an electrically-insulating material. As an example, the fourth layer is made of alumina (Al₂O₃).

Fourth insulating layer 114 coats the lateral surfaces and the lower surface of the vertical portion of the T formed by electrode 112G. Further, fourth insulating layer 114 laterally further extends on either side of the vertical portion and under the horizontal portion of the T formed by electrode 112G. Layer 114 extends on top of and in contact with the upper surface of third layer 108.

In the shown example, the horizontal portion of the T formed by electrode 112G extends on top of and in contact with portions of layer 114. These portions of layer 114 are thus vertically interposed between third layer 108 and the horizontal portion of the T formed by electrode 112G.

Generally, the portion(s) of fourth layer 114 which insulate gate electrode 112G from layers 104, 106, and 108 are considered as forming part of the gate region 100G of transistor 100.

Transistor 100 further comprises two other electrodes 1125 and 112D. Electrodes 1125 and 112D are located on either side of the gate region 100G of transistor 100, that is, on either side of gate electrode 112G. In the shown example, electrode 1125 is closer to gate region 100G than electrode 112D. As an example:
electrode 112S is separated from electrode 112G by a distance in the range from 1 μm to 2 μm, for example equal to 1 μm; and
electrode 112D is separated from electrode 112G by a distance in the range from 10 μm to 20 μm, for example, equal to 10 μm, to ensure a breakdown voltage for example ranging up to 1,000 V (the maximum electric field in GaN theoretically is 2 MV/cm, but it is in practice for example limited to 1 MV/cm by the quality of GaN layer 104).

In the shown example, electrodes 112S and 112D each vertically extend, from the upper surface of fourth insulating layer 114, towards the upper surface 102T of substrate 102. More precisely, in the shown example, electrodes 112S and 112D each cross layers 114, 108, and 106 and partially penetrate into the thickness of layer 104, for example at the end of a thermal anneal enabling to form a conductive alloy between electrodes 112S, 112D, and layer 106.

Electrodes 112S and 112D are each made of an electrically-conductive material, for example a metal or a metal alloy.

As an example, when transistor 100 is operating, electrode 112S is a source electrode and electrode 112D is a drain electrode. Electrode 112D being more distant from electrode 112G than electrode 112S, this enables to apply a high potential, for example in the order of 650 V, to electrode 112D without risking a breakdown of transistor 100, electrodes 112S and 112G being generally submitted to potentials in the order of a few volts.

In the shown example, electrodes 112S and 112D respectively form part of a source region 100S (Source) and of a drain region 100D (Drain) of transistor 100.

In HEMT transistor 100, a two-dimensional electron gas 2DEG forms in first gallium nitride layer 104, close to the interface between layer 104 and second aluminum-gallium nitride layer 106. The two-dimensional electron gas 2DEG is, in FIG. 1, represented by a dotted line. The electrodes 112S and 112D of HEMT transistor 100 are each in contact with the two-dimensional electron gas 2DEG.

In the shown example where HEMT transistor 100 is normally off, the two-dimensional electron gas 2DEG is interrupted by gate region 100G. More precisely, in this example, the two-dimensional electron gas 2DEG is discontinuous and comprises two portions located on either side of the gate region 100G of transistor 100 (on the left-hand side and on the right-hand side of region 100G, in the orientation of FIG. 1).

In operation, when a substantially zero voltage Vgs is applied between gate electrode 112G and source electrode 112S, the gate region 100G recessed in gallium nitride layer 104 prevents an electrons flow between source electrode 112S and drain electrode 112D. Transistor 100 then is in an off state.

However, when the voltage Vgs applied between gate electrode 112G and source electrode 112S exceeds a threshold voltage Vth of transistor 100, electrons may flow between source electrode 112S and drain electrode 112D. Transistor 100 then is in an on state.

In the on state, electrons flow from one portion to the other of the two-dimensional electron gas 2DEG around gate region 100G. More precisely, when transistor 100 is on and submitted to a bias voltage applied between its drain 100D and its source 100S, the electrons then follow, to flow from one side to the other of gate 100G, a conduction path located inside of first layer 104 and extending alongside the interface between layer 104 and fourth layer 114.

The conduction path followed by the electrons to bypass gate region 100G is, in FIG. 1, symbolized by arrows 116L, 116B, and 116R. More particularly, in the orientation of FIG. 1:
arrow 116L symbolizes the path followed by the electrons to flow down along a side of the gate region 100G located in front of source electrode 100S;
arrow 116B symbolizes the path followed by the electrons to displace horizontally under the lower surface of the vertical portion of the T formed by gate region 100G;
arrow 116R symbolizes the path followed by the electrons to flow up along another side of gate region 100G located in front of drain electrode 100D.

A disadvantage of HEMT transistors similar to transistor 100 lies in the fact that they have, in the on state, a high drain-source resistance Ron, which tends to strongly degrade their electric performance. This is particularly due to the conduction path 116L, 116B, 116R followed by the electrons to bypass gate region 100G.

To decrease the on-state resistance Ron of transistor 100, it may be devised to provide a structure where insulating layer 114 would be omitted and where gate electrode 112G would not penetrate into first gallium nitride layer 104. This would for example amount to ascertaining that electrode 112G stops, in the thickness of second layer 106, before the interface between layer 106 and layer 104. A Schottky gate, which would enable to locally interrupt or attenuate the two-dimensional electron gas 2DEG vertically in line with gate electrode 112G to obtain a normally-off transistor, would then be formed. However, this would not enable to reach a threshold voltage Vth greater than approximately 1 V, which is a problem for most applications using such transistors.

It could further be devised to form a structure where gate region 100G would not be recessed in stack 110. This would for example amount to forming a gate electrode on top of and in contact with layer 108. As an example, an implantation of fluorine ions (F⁺) may in particular be provided in layer 106, vertically in line with the gate electrode, which would result in attenuating or in interrupting the two-dimensional electrons gas 2DEG under the transistor gate. This would however tend to complicate the control of threshold voltage Vth.

It could as an alternative be provided to omit layer 114, to form the gate electrode of the transistor above layer 108, and to interpose a P-type doped gallium nitride layer (p-GaN) between the gate electrode and layer 108. However, this would not enable to reach threshold voltage values Vth sufficiently high for the targeted applications.

It could further be devised to decrease the width of the lower surface of the vertical portion of the T formed by gate region 100G, to decrease the length of horizontal conduction path 116B. However, this would not enable to significantly decrease the on-state resistance Ron of transistor 100.

FIG. 2 is a partial simplified cross-section view of an embodiment of a transistor 200 according to the invention. Like the transistor 100 of FIG. 1, transistor 200 is a normally-off HEMT transistor.

The transistor 200 of FIG. 2 comprises elements common with the transistor 100 of FIG. 1. The common elements will not be detailed again hereafter.

The transistor 200 of FIG. 2 differs from the transistor 100 of FIG. 1 mainly in that transistor 200 comprises an electrically-conductive layer 202 coating one of the sides of gate region 100G. Conductive layer 202 is symbolized, in FIG. 2, by a hatched area.

According to an embodiment, conductive layer 202 coats the side of gate region 100G which is located in front of electrode 100S, that is, the electrode closest to region 100G among electrode 100S and electrode 100D. More precisely, on the side of electrode 100S, layer 202 is interposed between:
the portion of insulating layer 114 coating the vertical portion of the T formed by electrode 112G; and
layers 104, 106, and 108.

In the shown example, conductive layer 202 laterally further extends on top of and in contact with the upper surface of layer 108, towards electrode 112S.

Layer 202 is made of an electrically-conductive material, for example a metal, a metal alloy or an N-type doped semiconductor. As an example, layer 202 is made of aluminum (Al), of gold (Au), of copper (Cu), or of titanium nitride (TiN).

In the shown example, the sides of the vertical portion of the T formed by gate region 100G are, in their lower portion, coupled by a horizontal portion. As a variant, the vertical portion of the T formed by region 100G has, in cross-section view, a triangular or “V” shape. In this case, the sides of the vertical portion of the T formed by gate region 100G meet in their lower portion.

An advantage of the transistor 200 of FIG. 2 over the transistor 100 of FIG. 1 lies in the fact that conductive layer 202 enables to decrease the resistance of the conduction path followed by electrons between electrode 100S and electrode 100D. More precisely, layer 202 enables to decrease the resistance of conduction path 116L (FIG. 1), in front of electrode 112S.

Along the conduction paths 116L and 116R of the transistor 100 of FIG. 1, the electrons indeed have a low mobility. As an example, the mobility of electrons in transistor 100, that is, in the absence of conductive layer 202, is in the order of 200 cm²/(V·s) along conduction path 116L and approximately 2,000 cm²/(V·s) in the two-dimensional electron gas 2DEG. The fact of providing conductive layer 202 coating a side of the gate region 100G of transistor 200 enables to obtain, along conduction path 116L, an electron mobility greater than that of transistor 100 (FIG. 1), for example substantially equal to the mobility in the two-dimensional electron gas 2DEG.

The presence of conductive layer 202 further enables to suppress or to limit a phenomenon of electron trapping in gallium nitride. Indeed, the electrons flowing along the conduction paths 116L, 116B, and 116R of transistor 100 are likely to be partially trapped by defects present in the material of first layer 104.

The trapping of electrons for example causes a hysteresis phenomenon on curves of the drain current Id versus a voltage Vgs applied between electrodes 112G and 112S (curves Id(Vgs)) and/or an attenuation (collapse) of drain current Id after the biasing of transistor 200 on curves of drain current Id versus a voltage Vds applied between electrodes 112D and 112S (curves Id(Vds)). In the case of transistor 200, the electron trapping phenomenon is strongly decreased along conduction path 116L (FIG. 1) since electrons preferably flow through conductive layer 202 and not through layer 104.

FIG. 3 is a partial simplified cross-section view of a variant of the transistor 200 of FIG. 2 according to the invention.

In this variant, the first gallium nitride layer 104 of transistor 200 comprises a P-type doped sub-layer. Layer 104 has, for example, a multilayer structure comprising:
a first sub-layer 104a (GaN), coating surface 102T of substrate 102;
a second P-type doped sub-layer 104b (p-GaN), coating first sub-layer 104a; and
a third sub-layer 104c (GaN), coating second sub-layer 104b.

First and third sub-layers 104a and 104c are made of intrinsic, that is, not intentionally doped, gallium nitride (GaN). Second sub-layer 104b, vertically interposed between sub-layers 104a and 104c, is made of P-type doped gallium nitride.

In this variant, the gate region 100G of transistor 100 crosses third and second sub-layers 104c and 104b, and may penetrate into the thickness of first sub-layer 104a. In other words, gate region 100G may further extend vertically into first sub-layer 104a.

An advantage of the variant discussed in relation with FIG. 3 lies in the fact that the threshold voltage Vth of transistor 200 may be adjusted by modifying a doping rate of second sub-layer 104b. More precisely, the threshold voltage Vth of the transistor 200 of FIG. 3 is all the higher as the doping rate of second sub-layer 104b is high.

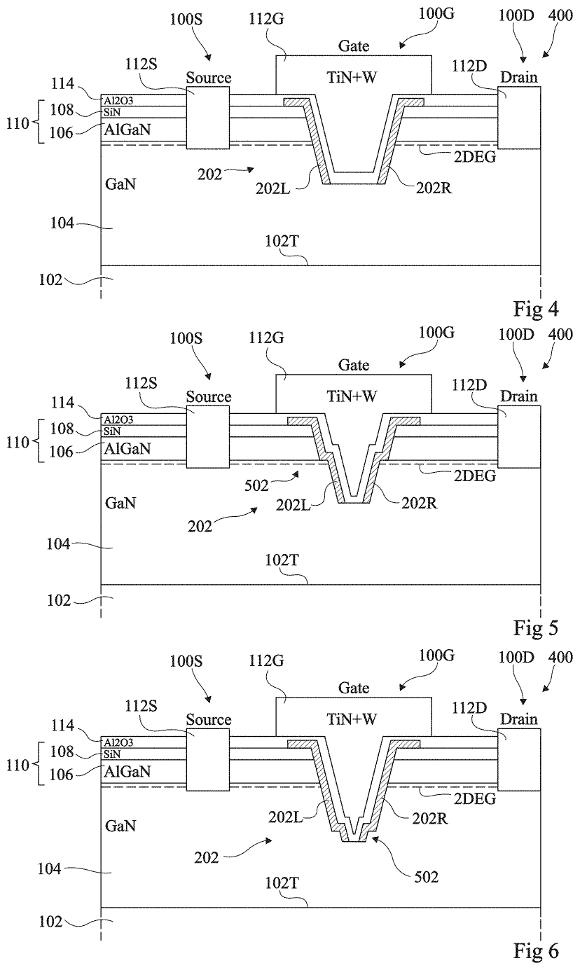

FIG. 4 is a partial simplified cross-section view of another embodiment of a transistor 400 according to the invention. The transistor 400 of FIG. 4 comprises elements common with the transistor 200 of FIG. 2. The common elements will not be detailed again hereafter.

The transistor 400 of FIG. 4 differs from the transistor 200 of FIG. 2 mainly in that the conductive layer 202 of transistor 400 coats both sides of gate region 100G. More precisely, according to this embodiment, the second layer 202 of transistor 400 is discontinuous and comprises:
a first portion 202L, coating the side of gate region 100G which is located in front of electrode 112S (on the left-hand side, in the orientation of FIG. 4); and
a second portion 202R, coating the side of gate region 100G which is located in front of electrode 112D (on the right-hand side, in the orientation of FIG. 4).

The two portions 202L and 202R of conductive layer 202 are represented, in FIG. 4, by hatched areas located on either side of the vertical portion of the T formed by gate electrode 112G.

The portion 202L of conductive layer 202 advantageously enables to decrease the resistance of conduction path 116L (FIG. 1). Similarly, the portion 202R of conductive layer 202 advantageously enables to decrease the resistance of conduction path 116R (FIG. 1). This enables transistor 400 to have an on-state resistance Ron still lower than that of the transistor 200 discussed in relation with FIG. 2. The electric performance of transistor 400 is thus further increased with respect to transistor 100 (FIG. 1).

The inventors have observed that the on—state resistance Ron of the transistor 100 of FIG. 1 was due, for approximately 40%, to the resistance of conduction paths 116L and 116R. The inventors have further observed that the fact of providing portions 202L and 202R of conductive layer 202 enables to decrease the contribution of conduction paths 116L and 116R for approximately 10% of the total resistance Ron in the case of transistor 400. A transistor 400 of higher performance than transistor 100 is thus obtained.

FIG. 5 is a partial simplified cross-section view of a variant of the transistor 400 of FIG. 4 according to the invention.

According to this variant, gate region 100G exhibits, in cross-section view in FIG. 5, at least one step 502. More precisely, in the shown example, the vertical portion of the T formed by gate electrode 112G exhibits, on each of its lateral surfaces, a shoulder. Similarly, insulating layer 114 and portions 202L and 202R of conductive layer 202 each exhibit a shoulder similar to those of gate electrode 112G.

In the shown example, the shoulders are approximately located at the level of aluminum-gallium nitride layer 106. As compared with the transistor 400 of FIG. 4, this enables to smooth an electric field originating from a biasing of drain electrode 112D with respect to gate electrode 112G. In other words, step 502 plays a role similar to that of a field plate.

FIG. 6 is a partial simplified cross-section view of another variant of the transistor 400 of FIG. 4 according to the invention. The variant illustrated in FIG. 6 differs from the variant previously discussed in relation with FIG. 5 mainly in that, in the transistor 400 of FIG. 6, step 502 is located across the thickness of first gallium nitride layer 104.

As compared with the transistor 400 of FIG. 4, this enables to further facilitate the flowing of electrons around gate region 100G. The on-state resistance Ron of transistor 400 is thus further decreased.

As a variant, conductive layer 202 (FIGS. 2 and 3) or the portion 202L (FIGS. 4 to 6) of conductive layer 202 located on the side of the source electrode 112S of transistor 200, 400 is connected to source electrode 112S. In this variant, layer 202 or portion 202L more precisely further extends on top of and in contact with the upper surface of layer 108, all the way to electrode 112S. Layer 202 or the portion 202L located on the side of electrode 112S thus has, in the vicinity of the bottom of electrode 112G, a potential substantially equal to that of source electrode 112S, for example, the ground (0 V).

An advantage of the alternative embodiment of transistors 200, 400 discussed hereabove lies in the fact that conductive layer 202, or the portion 202L of layer 202, extends from source electrode 112S to the vicinity of the bottom of gate electrode 112G. This enables electrons to more easily flow between source electrode 112S and the bottom of electrode 112G. Due to the fact that conductive layer 202 or portion 202L extends all the way to electrode 112S, a conduction path more favorable than that running through the two-dimensional electron gas 2DEG located in gallium nitride layer 104, 104c is particularly obtained.

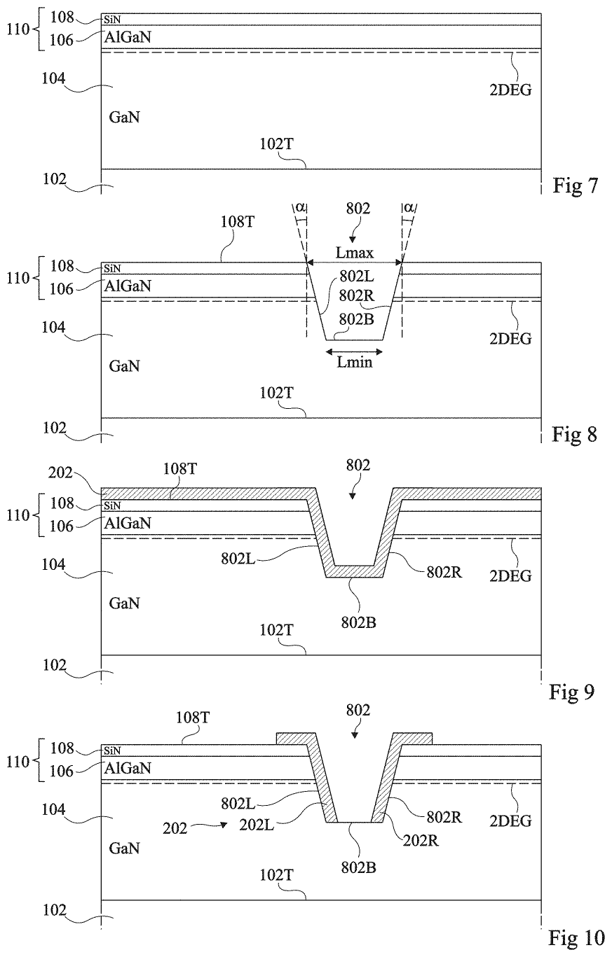

FIGS. 7 to 12 hereabove illustrate successive steps of an example of implementation of a method of manufacturing the transistor 400 of FIG. 4 according to the invention.

FIG. 7 is a partial simplified cross-section view illustrating a step of an implementation mode of a method of manufacturing the transistor 400 of FIG. 4.

During this step, first layer 104 (GaN), second layer 106 (AlGaN), and third layer 108 (SiN) are deposited on the side of surface 102T of substrate 102. More precisely, in the orientation of FIG. 7:
first layer 104 extends continuously over the entire upper surface 102T of substrate 102;
second layer 104 extends continuously over the entire upper surface of first layer 104; and
third layer 108 extends continuously over the entire upper surface of second layer 106.

Layers 104, 106, and 108 are for example formed by epitaxy. Although this is not shown in FIG. 7, an intermediate aluminum nitride layer (AlN) may be interposed between layers 104 and 106. This particularly enables to favor the epitaxy of aluminum-gallium nitride layer 106 on gallium nitride layer 104.

In FIG. 7, two-dimensional electron gas 2DEG extends laterally and continuously in first layer 104, under the interface between layers 104 and 106.

FIG. 8 is a partial simplified cross-section view illustrating another step of the implementation mode of the method of manufacturing the transistor 400 of FIG. 4.

During this step, a trench 802 extending vertically from an upper surface 108T of layer 108 is etched. More precisely, in the shown example, trench 802 crosses layers 108 and 106 of stack 110 and partially penetrates into the thickness of layer 104.

Trench 802 is for example formed by atomic layer etching (ALE).

According to an implementation mode, it is ascertained that trench 802 has, in cross-section view in FIG. 8, oblique lateral walls 802L and 802R. More precisely, trench 802 is etched so that its lateral walls 802L and 802R each form an angle α relative to a normal to the upper surface 108T of layer 108. The angle α formed by walls 802L and 802R is in the range from 5° to 45°, preferably equal to approximately 10°.

Lateral walls 802L and 802R are inclined so that trench 802 has, in cross-section view in FIG. 8, a flared profile. More precisely, it is ascertained that the trench has an opening (at the top, in the orientation of FIG. 8) wider than its bottom 802B (at the bottom, in the orientation of FIG. 8).

The lateral walls 802L and 802R of trench 802 form the sides of the gate region 100G of transistor 400 (FIG. 4). More specifically:
wall 802L forms the side of gate region 100G located in front of electrode 112S (FIG. 4); and
wall 802R forms the side of gate region 100G located in front of electrode 112D (FIG. 4).

The fact of providing a trench 802 having oblique lateral walls 802L and 802R enables, when transistor 400 (FIG. 4) is in the conductive state, to facilitate the flowing of electrons around gate region 100G. This more precisely enables to facilitate the flowing down of electrons along the side of the gate region 100G located in front of electrode 100S, that is, parallel to wall 802L of trench 802.

The fact of providing oblique walls 802L and 802R further enables to obtain a lower wall 802B narrower than in the case of a trench 802 having vertical walls 802L and 802R. This tends to decrease the on-state resistance Ron of transistor 400 (FIG. 4) by decreasing the length of horizontal conduction path 116B (FIG. 1) under gate region 100G.

As an example, trench 802 has:
a maximum width Lmax in the range from 0.4 μm to 1 μm, for example equal to approximately 0.5 μm; and
a minimum width Lmin in the range from 0.2 μm to 0.4 μm, for example equal to approximately 0.3 μm.

At the end of this step, the two-dimensional electron gas 2DEG is discontinuous. More precisely, trench 802 separates the two-dimensional electron gas 2DEG into two portions located on either side of trench 802.

FIG. 9 is a partial simplified cross-section view illustrating still another step of the implementation mode of the method of manufacturing the transistor 400 of FIG. 4.

During this step, lateral walls 802L and 802R and bottom 802B of trench 802 are coated with conductive layer 202. In the shown example, layer 202 extends laterally, on either side of trench 802, on top of and in contact with the upper surface 108T of layer 108.

Layer 202 is for example formed by a conformal deposition technique, for example, by chemical vapor deposition (CVD). The material forming layer 202 is for example selected to obtain a low lattice parameter mismatch with respect to the material of layer 104. The presence of crystal defects is thus avoided or limited at the interface between layers 104 and 202, these defects being likely to form trap states for electrons.

As an example, layer 202 has a thickness in the range from 5 nm to 20 nm, for example, equal to approximately 10 nm.

FIG. 10 is a partial simplified cross-section view illustrating still another step of the implementation mode of the method of manufacturing the transistor 400 of FIG. 4.

During this step, layer 202 is etched to only keep portions 202L and 202R of layer 202 which respectively coat the lateral walls 802L and 802R of trench 802. In the shown example, the portion of layer 202 covering the bottom 802B of trench 802 and most of the portions of layer 202 which coat the upper surface 108T of layer 108 are removed.

In practice, as shown in FIG. 9, portions of layer 202 coating the upper surface 108T of layer 108 may be kept on either side of the opening of trench 802.

Portions 202L and 202R of layer 202 are preferably obtained by a wet etching method. This particularly enables to obtain a good roughness at the level of bottom 802B of trench 802. The on-state resistance Ron of transistor 400 is thus decreased (FIG. 4).

As a variant, the wet etching is preceded by a step of dry etching, for example by means of plasma. In this case, the wet etching enables to improve the surface state, obtained at the end of the dry etching step, of the bottom 802B of trench 802.

Generally, it is desired to obtain an ohmic contact between portions 202L, 202R of layer 202 and two-dimensional electron gas 2DEG. This particularly enables to avoid the occurrence of a voltage drop at the level of the interface between the gallium nitride of layer 104 and the material of layer 202.

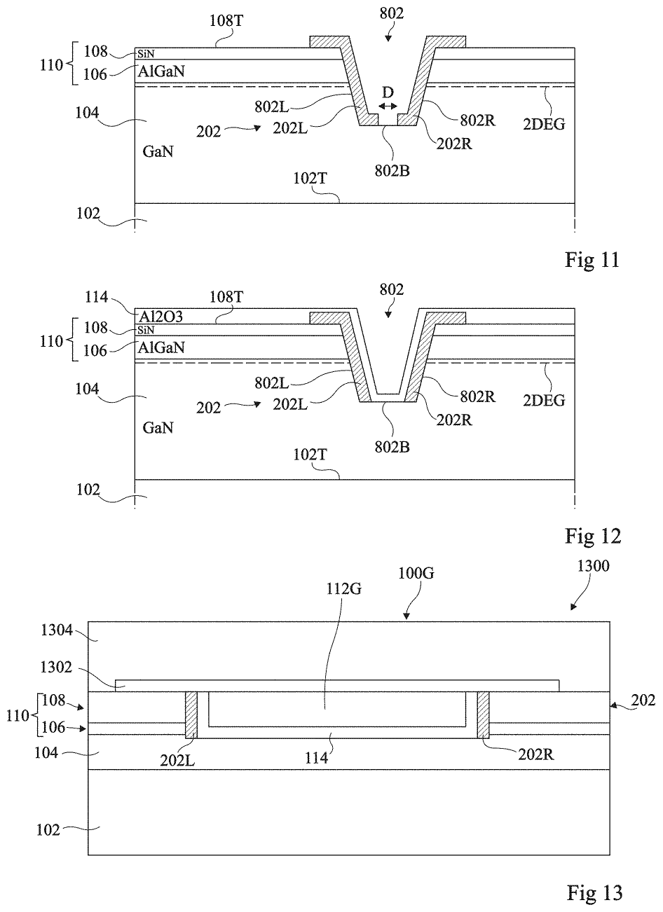

FIG. 11 is a partial simplified cross-section view illustrating a variant of the step discussed in relation with FIG. 10.

In this variant, conductive layer 202 is etched so that portions 202L and 2902R partially coat the bottom 802B of trench 802. In the shown example, the portion 202L of layer 202 further extends on top of and in contact with the bottom 802B of trench 802. Similarly, the portion 202R of layer 202 further extends on top of and in contact with the bottom 802B of trench 802.

It is however ascertained that portions 202L and 202R of layer 202 remain separate. Generally, it is ascertained that portions 202L and 202R of layer 202 are separated by a distance D sufficient to avoid any risk of breakdown due to the biasing of the drain electrode 112D (FIG. 4) of transistor 400. As an example, distance D is greater than approximately 100 nm.

The fact of further extending the portions 202L and 202R of layer 202 on the bottom 802B of trench 802 enables to avoid or to limit the occurrence of edge effects likely to increase the on-state resistance Ron of transistor 400 (FIG. 4).

In the following description, it is assumed that the variant discussed in relation with FIG. 11 is not retained. However, the adaptation of the steps discussed hereafter to the variant of FIG. 11 is within the abilities of those skilled in the art.

FIG. 12 is a partial simplified cross-section view illustrating still another step of the implementation mode of the method of manufacturing the transistor 400 of FIG. 4 from the structure obtained at the end of the step described in relation with FIG. 10.

During this step, the upper surface of the structure obtained at the end of the step described in relation with FIG. 10 is coated with insulating layer 114. More precisely, in the shown example, layer 114 coats:
the exposed portions of the upper surface 108T of layer 108;
the exposed portions of the portions 202L and 202R of conductive layer 202; and
the exposed portion of the bottom 802B of the trench 802 located between portions 202L and 202R.

Insulating layer 114 is for example made of alumina (Al₂O₃) or of silica (SiO₂). In the case of an alumina layer 114, a deposition of a layer of aluminum nitride (AlN) may precede the deposition of layer 114. This for example allows a better lattice parameter matching between layers. The number of defects likely to be present at the interface is thus decreased.

Layer 114 is preferably formed by a conformal deposition technique. This enables to obtain a uniform layer 114. This advantageously results in a more uniform capacitive coupling thus enabling to avoid the presence of field peaks.

Based on the structure described in relation with FIG. 12, electrodes 112S, 112G, and 112D are then formed to obtain the transistor 400 discussed in relation with FIG. 4. As an example, electrodes 112S, 112G, and 112D are obtained by deposition and then local etching of a metal layer (not shown) coating the upper surface of insulating layer 114.

Generally, the forming of electrodes 112S, 112G, and 112D from the structure obtained at the end of the step discussed in relation with FIG. 12 is within the abilities of those skilled in the art.

FIG. 13 is a partial simplified cross-section view of still another embodiment of a transistor 1300 according to the invention. The transistor 1300 of FIG. 13 comprises elements common with the transistor 400 of FIG. 4. These common elements will not be detailed again hereafter.

The transistor 1300 of FIG. 13 differs from the transistor 400 of FIG. 4 mainly in that the portions 202L and 202R of layer 202 of transistor 1300 are vertical and not oblique as in the case of transistor 400. Further, the gate electrode 112G of transistor 1300 is topped with a field plate 1302. In the shown example, the field plate 1302 of transistor 1300 coats the upper surface of gate electrode 112G and extends laterally on top of and in contact with the upper surface of stack 110. Field plate 1302 is for example made of silica (SiO₂).

Other layers may be formed above field plate 1302 and the exposed portions of the upper surface of stack 110. These layers are symbolized, in FIG. 13, by a region 1304.

It is assumed, in the rest of the disclosure, that transistor 1300 has, on either side of gate region 100G, electrodes similar to the electrodes 112S and 112D of the transistor 400 of FIG. 4.

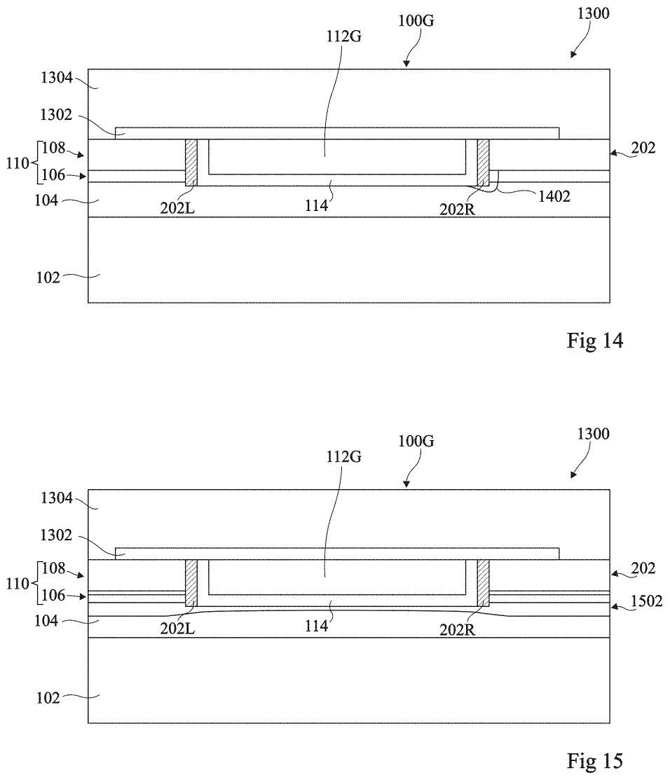

FIG. 14 is a partial simplified cross-section view illustrating an electron density inside of the transistor 1300 of FIG. 13 in an operating mode.

In the operating mode of FIG. 14, transistor 1300 is assumed to be off. As an example, this corresponds to a situation where:
a voltage Vds equal to approximately 650 V is applied between the drain electrode (not shown) and the source electrode (not shown) of transistor 1300; and
a substantially zero voltage Vgs is applied between the gate electrode 112G and the source electrode (not shown) of transistor 1300.

Assuming, in the orientation of FIG. 14, that the drain and source electrodes (not shown) of transistor 1300 are respectively located on the right-hand side and on the left-hand side of gate region 100G, a high electron density area 1402 forms close to the lower end of portion 202R of conductive layer 202. Area 1402 is due to an electric field attracting electrons on the side of drain electrode 112D. As an example, the electron density reaches approximately 1.5×10¹⁸ per cubic centimeter in area 1402 while it is approximately zero in the other portions of transistor 1300 shown in FIG. 14.

Area 1402 does not sufficiently extend laterally for a breakdown to occur between the drain electrode (not shown) and the portion 202R of conductive layer 202. In other words, the presence of portion 202R of conductive layer 202 does not adversely affect the operation in the off state of transistor 1300.

FIG. 15 is a partial simplified cross-section view illustrating the current density inside of the transistor 1300 of FIG. 13 in another operating mode.

In the operating mode of FIG. 15, transistor 1300 is assumed to be on. As an example, this corresponds to a situation where:
voltage Vds is equal to approximately 0.5 V; and
voltage Vgs is equal to approximately 6 V.

In this operating mode, an area 1502 of high current density forms under the gate region 100G of transistor 1300. As an example, the current density reaches approximately 8×10⁵ amperes per square centimeter in area 1502 while it is substantially zero in the other portions of the transistor 1300 shown in FIG. 15.

In FIG. 15, it can be observed that the presence of portions 202L and 202R of conductive layer 202 improves the operation in the on state of transistor 1300, since the current density under gate 100G is substantially identical to the current density on either side of gate 100G.

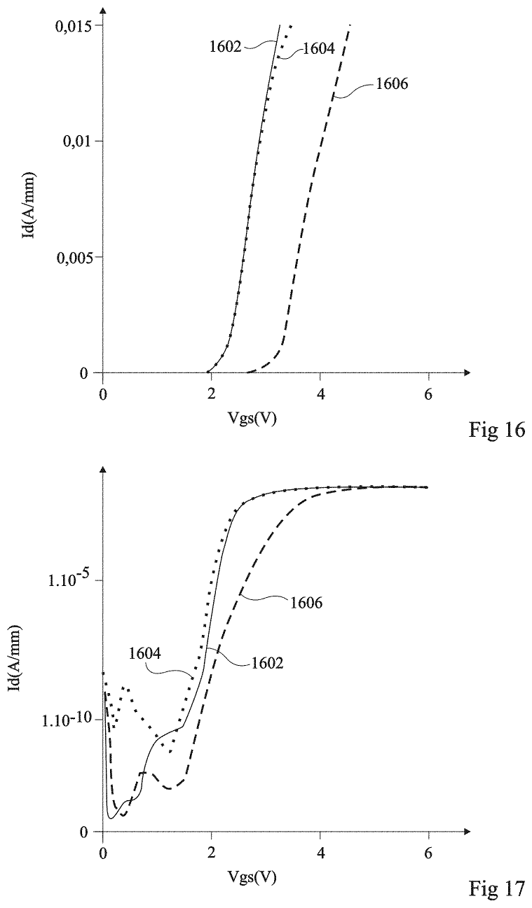

FIG. 16 is a graph of the variation of a drain current Id (in ordinates), according to the gate-source voltage Vgs (in abscissas) of the transistor 1300 of FIG. 13. Current Id is expressed in amperes per millimeter (A/mm), according to a linear scale, and voltage Vgs is expressed in volts (V).

FIG. 16 more precisely illustrates the variation of drain current Id according to gate-source voltage Vgs for portions 202L and 202R of conductive layer 202 (FIG. 13) based on:
aluminum (curve 1602 represented by a continuous line);
copper (curve 1604 represented by a dots); and
a theoretical example of a metal having a work function equal to approximately 8 eV (curve 1606 represented by dashes).

In FIG. 16, it can be observed that current Id is substantially zero for voltage values Vgs smaller than 2 V and progressively increases:
from approximately 2.1 V for curves 1602 and 1604; and
from approximately 2.8 V for curve 1606.

It can be deduced, in this example, that transistor 1300 has a threshold voltage Vth:
equal to approximately 2.1 V if its conductive layer 202 is made of copper or of aluminum; and
equal to approximately 2.8 V if its conductive layer 202 is made of a metal having an 8-eV work function.

More generally, the fact of selecting a material of layer 202 having a high work function enables to increase the threshold voltage Vth of transistor 1300. In the case of a transistor comprising no conductive layer 202, a threshold voltage Vth of approximately 1 V would be obtained, that is, an associated curve Id(Vgs) located to the left of curves 1602, 1604, and 1606 in the orientation of FIG. 16.

The presence of conductive layer 202 enables transistor 1300 to have both a low on-state resistance Ron and a threshold voltage Vth greater than 1.5 V, for example, greater than 2 V.

FIG. 17 is another graph of the variation of drain current Id (in ordinates), according to the gate-source voltage Vgs (in abscissas) of the transistor 1300 of FIG. 13. Current Id is expressed in amperes per millimeter (A/mm), according to a semi-logarithmic scale, and voltage Vgs is expressed in volts (V).

It can be observed, from curves 1602, 1604, and 1606 of FIG. 17, that drain current Id remains low, for example, lower than 1×10¹⁰ amperes/mm as long as gate-source voltage Vgs is lower than threshold voltage Vth. In other words, this confirms that the presence of the portions 202L and 202R of conductive layer 202 does not adversely affect the operation of transistor 1300 in the off state, where a current Id as low as possible is desired to be obtained.

An advantage of the embodiments and implementation modes described hereabove lies in the fact that the inclined sides of the vertical portion of the T formed by gate electrode 112G enable to improve the electric performance of the described devices. The uniformity of layer 114 further enables to further improve this performance.

Various embodiments, implementation modes, and variants have been described. Those skilled in the art will understand that certain features of these various embodiments, implementation modes, and variants, may be combined and other variants will occur to those skilled in the art. In particular, those skilled in the art are capable of adapting:
the variant discussed in relation with FIG. 3 to the transistor 300 of FIGS. 4 to 6 and to the transistor 1300 of FIGS. 13 to 15;
the variant discussed in relation with FIGS. 5 and 6 to the transistor 400 of FIGS. 2 and 3 and to the transistor 1300 of FIGS. 13 to 15; and
the embodiment of the transistor 200 of FIG. 2 to the transistor 1300 of FIGS. 13 to 15.

Those skilled in the art are further capable of adapting the implementation mode of the method described in relation with FIGS. 7 to 12 to obtain the different above-described embodiments and variants. Those skilled in the art are particularly capable of adapting this method to the forming of the variant where conductive layer 202 or portion 202L contacts the source electrode 112S of transistor 200, 400.

Finally, the practical implementation of the described embodiments, implementation modes, and variants is within the abilities of those skilled in the art based on the functional indications given hereabove. In particular, the choices for the geometry of gate region 100G, for the thickness of conductive layer 202, and for the materials used are within the abilities of those skilled in the art.

1. Transistor comprising a gate region penetrating into a first gallium nitride layer, wherein a second electrically-conductive layer coats at least one of the sides of said gate region, said sides being, in side view, inclined towards the middle of said gate region by an angle in the range from 5° to 45°, preferably equal to approximately 10°.

2. Transistor according to claim 1, further comprising a first electrode and a second electrode, located on either side of the gate region and penetrating into the first layer, the first electrode being closer to the gate region than the second electrode.

3. Transistor according to claim 2, wherein the second layer coats the side of the gate region located in front of the first electrode and further extends all the way to the second electrode.

4. Transistor according to claim 1, wherein the first layer coats a surface of a semiconductor substrate.

5. Transistor according to claim 4, wherein the first layer has a multilayer structure comprising:
a first sub-layer, coating said surface of the substrate;
a second P-type doped sub-layer, coating the first sub-layer; and
a third sub-layer, coating the second sub-layer,
the gate region crossing the third and second sub-layers and further extending inside of the first sub-layer.

6. Transistor according to claim 4, further comprising, on the side of said surface, a stack comprising:
a fourth aluminum-gallium nitride layer, coating the first layer; and
a fifth silicon nitride layer, coating the fourth layer.

7. Transistor according to claim 2, wherein the gate region comprises:
a third gate electrode; and
a third electrically-insulating layer interposed between the third electrode and the first layer.

8. Transistor according to claim 2, wherein:
the first electrode is a source electrode forming part of a source region of the transistor; and
the second electrode is a drain electrode forming part of a drain region of the transistor.

9. Transistor according to claim 2, wherein the second layer is discontinuous and comprises:
a first portion, coating the side of the gate region located in front of the first electrode; and
a second portion, coating the side of the gate region located in front of the second electrode.

10. Transistor according to claim 1, wherein the gate region exhibits, in cross-section view, at least one step.

11. Method of manufacturing a transistor according to claim 1.
